(19) United States
(12) Patent Application Publication
(10) Pub. No.: US 2019/0237602 A1
(43) Pub. Date: Aug. 1, 2019

(54) DELAMINATION-PREVENTING COMPOSITE SEALING MATERIAL AND SOLAR CELL MODULE

(71) Applicant: HYBRID PHOTOVOLTAIC RESEARCH LABORATORIES LIMITED, OKAZAKI-SHI (JP)

(72) Inventor: HIDENARI NAKAHAMA, OKAZAKI-SHI (JP)

(73) Assignee: HYBRID PHOTOVOLTAIC RESEARCH LABORATORIES LIMITED, OKAZAKI-SHI (JP)

(21) Appl. No.: 16/254,733

(22) Filed: Jan. 23, 2019

(30) Foreign Application Priority Data
Jan. 26, 2018 (JP) 2018-011645

(51) Int. Cl. H01L 31/048; H01L 31/049; H01L 31/068

(52) U.S. Cl. CPC H01L 31/0481; H01L 31/0682; H01L 31/049

(57) ABSTRACT

In a super straight solar cell module structure, a solar cell module that remains delamination-free over an ultralong period of time can be provided by using a composite filling material obtained by sandwiching, by an EVA sealing material with a melting point of 55° C. or higher and 75° C. or lower, a cyclic olefin-based copolymer film having a glass transition temperature ranging from 70° C. to 80° C. and a thickness ranging from 20 μm to 50 μm.

### CROSS REFERENCE TO RELATED APPLICATION

This application claims priority to Japanese Patent Application No. 2018-011645 filed on Jan. 26, 2018, which is hereby incorporated by reference herein in its entity.

### BACKGROUND

The present invention relates to a delamination-preventing composite sealing material and a solar cell module and, specifically, to a sealing material of a solar cell power generating element in a solar cell module, a method of manufacturing the sealing material, and a solar cell module fabricated using the sealing material. More specifically, the present invention relates to a delamination-preventing film for a solar cell which completely prevents a delamination (interlayer peeling) failure from occurring during an ultralong period of time by being disposed between a cover glass and a power generating element or between a back sheet and a power generating element or being disposed by lamination on front and rear surfaces of a power generating element, and to a solar cell module using the delamination-preventing film.

The production of solar cell modules is increasing year after year, gradually making solar cell modules a key energy source to supersede nuclear power plants which have previously been considered representative low carbon power sources. In the Middle East, with costs as low as 2 cents/W, solar cell modules are becoming a major energy source in both name and substance. A drop in unit cost per watt or, in other words, an improvement in conversion efficiency of cells is a major contributor to the expansion of production of solar cell modules. As far as crystalline solar cell modules are concerned, in addition to cost reductions of monocrystalline wafers, PERC cells, heterojunction cells, N-type cells, and the like have been successively developed and introduced to the market.

An increase in the number of interconnectors has also contributed to higher power generation efficiency. The number of interconnectors has increased from two to three and then to four, which has become the mainstream, and a further increase to five is expected to become a reality in the near future. Accordingly, a line width of finger electrodes has become narrower and, in the case of five interconnectors, 210 fingers are to be arranged at intervals of 30 μm. As a result, there is an increasing trend in an amount of irregularities on a cell surface. On the other hand, it is known that the greater a sectional area of an interconnector, the lower the electrical resistance thereof and the greater a contribution toward improving power generation conversion efficiency of a module. While an interconnector is typically 120 μm in height, types of interconnectors with greater thicknesses of 150 μm and even 200 μm are being increasingly adopted with an aim to improve power generation efficiency. As described above, in consideration of the fact that lamination processing of a sealing material on a cell is becoming increasingly difficult, there is a need for new materials including sealing materials that accommodate the irregularities on a cell surface.

In industrial photovoltaic power generation, there are two problems that result in replacement of a solar cell module: potential induced degradation (PID) and delamination failure.

PID is a phenomenon that occurs in large-scale photovoltaic power stations in which output suddenly drops. PID is a fairly common occurrence in mega solar plants. One of the causes of PID is the application of a specific environment such as high humidity and high temperature to a state where a large difference in potential or voltage is created between a solar cell and a frame of a solar cell module. At this point, generated currents are collected by a finger electrode on the cell. In addition, along a path by which a current flows in series to a junction box cable of a panel through an interconnector, the current is shunted (shorted) inside the cell instead of flowing to the electrode of the interconnector. This current is called a “leakage current” and is known to have a large bearing on promoting degradation in a phenomenon of power generation degradation of a solar cell module. Since a cell in which PID has occurred is no longer capable of generating power even when exposed to sunlight, this phenomenon represents a dramatic decrease in power generation. Although this phenomenon is considered to occur with respect to grounding in a transformer-less configuration, transformers are hardly installed due to high plant equipment cost and low DC/AC conversion efficiency. Currently, many PID-free products made possible by countermeasures implemented on solar cell modules are being manufactured.

There is an abundance of patent literature on PID countermeasures. Japanese Patent No. 5965004 represents a technical disclosure ranging from a mechanism to a countermeasure of PID. Japanese Translation of PCT Application No. 2013-502051 presents a technique of stacking a high-insulation film constituted by a fluorine-based film or the like between a cell and a cover glass. Meanwhile, Japanese Patent Application Laid-open No. 2008-273783 presents a surface treatment technique of a glass surface by a silane coupling agent for reducing an effect of alkali metal released from the glass. In addition, Japanese Patent Application Laid-open No. 2006-198922 discloses a solar cell module having a layer made of a cyclic olefin-based resin and layers made of an ethylene-vinyl acetate copolymer, wherein at least one of the layers made of an ethylene-vinyl acetate copolymer is disposed on a side distant from the solar cell module with respect to the layer made of a cyclic olefin-based resin.

Japanese Patent Application Laid-open No. 2015-179827 discloses a mechanism that generates a PID phenomenon and a PID countermeasure involving laminating a cyclic olefin-based resin film between a cover glass and a cell as a sodium barrier layer. In a P-type silicon semiconductor, when sodium ions accumulate and cover an area equal to or greater than approximately 15% of a cover glass-side area of a silicon cell, a portion (equal to or greater than 15% by area) of an n layer of a pn structure is converted into p-type. Consequently, a shunt current flows to the portion and causes the cell to lose its semiconductor properties and its ability to generate power. In other words, the patent document argues that a PID phenomenon is a cell-related problem and, as a countermeasure, disposing a sodium barrier film between glass and a power generating element enables an occurrence of PID to be prevented.

FIG. 1 shows a situation where delamination (clouding) has occurred. This is a phenomenon in which a clouded portion of a sealing material spreads from an interconnector as its origin. The clouded portion originates in an interconnector portion of a cell in the vicinity of an edge portion of a solar cell module and expands along the interconnector. The clouded solar cell module is externally defective and must be replaced. This is a horrific event from the perspective of a solar cell module manufacturer. While this problem was previously limited to power plants in operation for 15 years or more, recently, occurrences have been reported at power plants that have only been operational for less than 10 years and are becoming a major concern.

In delamination, due to peeling of a sealing material from a cell, the affected portion appears clouded due to scattering of light. In other words, delamination is a problem of “adhesion loss” between an EVA sealing material and a cell surface at an interconnector and a periphery thereof. As things stand, since a mechanism of delamination occurrence in a solar cell module is yet to be defined, there are no technical countermeasures and the only course of action is “panel replacement” within the coverage under product warranty of the solar cell module.

### SUMMARY

Delamination may occur in solar cell modules that have been operational for 10 years or more as well as around 20 years. In addition, occurrences are localized in cells in a periphery portion of a solar cell module and to interconnector portions of cell surfaces. Delamination proceeds along the interconnectors and takes the form of peeling of an EVA sealing material. Further close observations reveal browning of a lateral busbar inside the module and a flow of the discolored portion in a frame direction.

Delamination is an “adhesive” failure between the periphery of an interconnector portion and the cell surface. As an invention to provide a countermeasure, the following was studied: 1. relationship between delamination and processing conditions of an EVA sealing material in consideration of resin characteristics of the EVA sealing material; 2. physical relationship between delamination and adhesion as expected from irregularities on the cell surface; and 3. relationship between delamination and environmental deterioration factors that affect long-term reliability of chemical adhesion between the cell surface and the sealing material. An object of the present invention is to provide a delamination-preventing film for a solar cell which completely prevents delamination from occurring, a composite sealing material incorporating the delamination-preventing film, and a solar cell module using the delamination-preventing film.

Intensive studies revealed that EVA sealing materials, which have already been in use for 50 years, exhibit highest adhesive strength in the adhesion between a cell surface, an interconnector, and a finger electrode. This is evidenced by EVA sealing materials being adopted in approximately 90% or more of the solar cell modules produced around the world. In other words, an EVA sealing material sheet represents an optimal sheet as a sealing material for a solar cell as an initial (authentication test conditions) mechanical adhesive sheet. Therefore, an EVA sealing material sheet is applied as a filling material to provide adhesion with a cover glass and sealing (adhesion) of cells. Hereinafter, a mechanism of delamination occurrence will be described, followed by a presentation of an invention that provides a countermeasure involving the application of an EVA sealing material.

An irregular portion between an interconnector and a finger electrode on a cell is the sole origin of delamination that occurs between an EVA sealing material and the cell surface.

In a lamination step of a solar cell module production process, on top of a cover glass prepared in a layup step as a bottommost portion, an EVA sealing sheet, a serially wired cell string, an EVA sealing sheet, and a back sheet as a topmost portion are laminated in this order to create a layer structure of a solar cell module. The layer structure is subsequently subjected to heat and pressure to mold the solar cell module. An aluminum frame and a junction box are attached to the solar cell module to obtain a product.

Processing conditions of the lamination are similar to those applied to die molding of a general rubber product. Specifically, since the cells are covered (sealed) with the EVA sealing sheets, molding is performed after preheating of EVA resin (a preheating step) and a pressing step which involves pressurization and thermosetting. In the field of solar cells, this preheating step is referred to as a “vacuum time” in which heat of a hot plate is transferred through glass to the EVA sealing material and then to the back sheet.

In the preheating step of a crystalline resin, the temperature must at least rise to or above the melting point (Tm) of the resin, and in the preheating step of an amorphous resin, the temperature must rise to or above the glass transition temperature (Tg). EVA is a crystalline resin and the melting point thereof varies depending on a content of vinyl acetate monomer to be copolymerized with ethylene. Generally, brands with melting points that vary from 40° C. to 90° C. are available.

Sizes of solar cell modules are becoming larger, and a module in which 60 silicon cells are arranged in series is called a “60 series type” which is approximately 900 mm wide and approximately 1600 mm long. Glass thickness slightly exceeds 3 mm, and a diaphragm rubber sheet that lacks functionality as a heat source presses the glass against a hot plate. Therefore, “warpage” of the glass occurs on the laminator hot plate. With a 60 series type, an edge portion of the glass is uplifted by up to around 5 cm. Therefore, a significant difference in temperature rise rates is created between a central portion and a peripheral portion of the glass. Pressurization by the diaphragm rubber sheet cannot be performed until the “warpage” of the glass decreases and the temperature of the EVA sealing material in the peripheral portion of the glass reaches or exceeds the melting point of the material.

Meanwhile, a state of an EVA sealing material covering a cell is shown in FIG. 4. A height of an interconnector is around half of the thickness of the EVA sealing material, and a “gap” (hatched portion) in the shape of a 45° right triangle, one side of which is the height of an interconnector, exists. Filling this gap portion in the lamination step is essential in realizing the functionality of “sealing”.

Filling the gap is a matter of resin processing, and a vacuum time suitable for the material is determined while obtaining temperature rise curves within a lamination processing time of central and peripheral portions on the glass surface. Filling the gap is also an important condition in terms of production quality management. The gap cannot be filled at a temperature lower than the melting point of EVA resin since the resin does not flow in a pressed portion (the peripheral portion of the glass) at such a temperature. Therefore, decomposition gas of organic peroxides produced simultaneously with an EVA cross-linking reaction concentrates in this portion and innumerable bubbles of around 0.1 to 1 mm are formed after the molding in the interconnector portions and lateral busbar portions of the cells in the periphery of the glass. Such a product is discarded as an externally defective item.

However, since a product in which a chemical adhesion reaction between an EVA sealing material and a cell interface stops in a simply insufficient state cannot be identified as an external defect, the product is shipped after standard output is confirmed and ends up being installed at a power plant. It is presumed that delamination failure occurs in such products after being operational for around ten years.

Currently, ultra-fast cure type EVA sealing materials which provide adhesive strength to cells at a faster rate are being used for the purpose of reducing production cost. Reducing processing time in the lamination step is considered a trump card in reducing production cost and, accordingly, production sites are constantly under pressure to reduce processing time.

The time required for EVA preheating described earlier cannot be reduced as long as the current processing method which inevitably involves the occurrence of “warpage” of glass is adopted. At production sites, studies to reduce preheating time by external product inspections for the purpose of cost reduction are being carried out on a daily basis. Under such circumstances, at production lines on which products are produced under conditions that create variations in temperature on a hot plate and portions where the temperature does not exceed the melting point of EVA resin, it is highly likely that products in which delamination can potentially occur around interconnectors end up being shipped out.

As described earlier, a delamination occurrence is related to flowability of the EVA sealing material affected by the processing conditions described above. Sealing the gap is an essential part of any delamination countermeasure. On this basis, a technique which enables a chemical adhesion structure between an EVA sealing material and a cell surface and irregular portions, and particularly between the EVA sealing material and an interconnector, to stabilize over a long period of time without being affected by environmental deterioration factors was studied, culminating in the present invention.

In order to solve the problems described above, a first aspect of the present invention provides a delamination-preventing film and a delamination-preventing composite sealing material being a composite sealing material constituted by a three-layer structure of (A) an ethylene-vinyl acetate copolymer (EVA) sealing material/(B) an ethylene-cyclic olefin copolymer film/(A) the EVA sealing material, the delamination-preventing film and the delamination-preventing composite sealing material satisfying qualities of (A) and (B) below as a filling material for a super straight-type solar cell module.
(A) A melting point (Tm) of the EVA sealing material as measured by DSC ranges from 55° C. to 75° C.
(B) A glass transition temperature (Tg) of the ethylene-cyclic olefin copolymer as measured by DSC ranges from 80° C. to 70° C. and a film thickness thereof ranges from 20 μm to 50 μm.

Since molecules of EVA resins include an ester structure, EVA resins are heat-sensitive and manufacturers recommend a lamination molding temperature of 150° C. or lower. On the other hand, having this polar group-vinyl acetate structure enables strong adhesion to silicon cells and glass to be exhibited through a silane coupling reaction. Therefore, in order to prevent delamination occurrence, an EVA sealing material capable of producing strong adhesion is used as a constituent material of the composite sealing material. The melting point of the EVA sealing material ranges from 55° C. to 75° C., favorably ranges from 58° C. to 70° C., and more favorably ranges from 60° C. to 65° C. A quality in which the melting point is lower than 55° C. means that the content of vinyl acetate is high and is unfavorable due to the likelihood of deterioration at the lamination molding temperature as well as the likelihood of an occurrence of deacetylation. A melting point higher than 75° C. is also unfavorable since such a temperature may exceed the temperature in the peripheral portion of glass during lamination processing and the “gap” around the interconnector described earlier may possibly be left unfilled.

After the irregular portions on the cell are filled with the EVA resin, a cross-linked structure of the EVA sealing material is formed by a cross-linking agent and radicals produced by the decomposition of organic peroxides and, at the same time, a polysilanol bonded structure is formed with the cell surface via the vinyl acetate contained in EVA and a silane coupling agent, thereby completing an adhesive reaction. The adhesive reaction proceeds under heat and pressure and, when insufficient, may lead to delamination occurrence. In the production process, products are produced while measuring an adhesive strength between cells and EVA and while making sure that a certain strength is being realized.

A molecular structure of EVA resin and a polysilanol structure of the adhesive interface are structures which are sensitive to humidity (water vapor) or, in other words, susceptible to hydrolysis. Furthermore, it is known that alkaline hydrolysis readily proceeds at room temperature in an alkaline environment. It was concluded that the cause of occurrences of delamination after long periods of ten years, twenty years, and the like is related to this hydrolytic reaction.

The ends of peripheral portions of glass bonded to an EVA sealing material are constantly susceptible to wetting by ran water. It is easily assumable that, in fair weather, a situation is created where the rain water inside the frame turns into water vapor capable of readily penetrating into the layer of the EVA sealing material. In addition, a “leakage current” is created from the glass to the frame during power generation. Accordingly, at the ends, alkalization occurs inside the glass as sodium migrates and an alkaline hydrolytic reaction takes place in the peripheral portions of the glass inside the frame. Starting from these locations, an inlet of a penetration path of water vapor is formed. When a “gap” is present in the irregular portions in the periphery of interconnectors, water vapor readily penetrates into the module and delamination proceeds along the interconnectors. Even when a “gap” is absent, delamination conceivably occurs in a similar manner in solar cell modules in which the adhesive strength around the interconnectors has declined (has become imperfect). Hydrolytic reactions proceed successively due to water vapor penetration on the adhesive interface in the periphery of interconnectors, and once delamination propagates and reaches cells positioned in the interior of the module, a fully-clouded solar cell module is realized.

In consideration of the mechanism of delamination occurrence described above, a filling material capable of preventing delamination was completed by using an EVA sealing material which exhibits maximum initial interface adhesion and providing a layer structure which is resistant to hydrolysis. FIG. 3 shows a layer structure of the composite sealing material. In order to impart a function resistant to passage of water vapor to the adhesive interface between the EVA sealing material and the cell surface, a structure in which a cyclic olefin film with an extremely high water vapor barrier property is sandwiched by the EVA sealing material was devised. In order to do so, the cyclic olefin film and the EVA must be integrated on the molecular level. Since the respective interfaces are integrated on the molecular level due to a cross-linking reaction, by an organic peroxide cross-linking agent containing EVA, of a radical moiety caused by hydrogen extraction between an ethylene sequence of the cyclic olefin film and an ethylene sequence of EVA, the present composite sealing material is capable of realizing a water vapor barrier property while retaining adhesion of EVA.

It is essential that Tg of the cyclic olefin film sandwiched by the EVA sealing material ranges from 70° C. to 80° C. Temperatures exceeding 80° C. give rise to the likelihood that the “gap” in the periphery of interconnectors is not filled in the lamination process and are therefore unfavorable. Temperatures below 70° C. are also unfavorable because panel temperatures in the field often rise to around 100° C. and, in such cases, the film shrinks and creates hexagonal wrinkle patterns on the cell surface. These wrinkles may develop into cracks through an annual heat cycle.

The lamination of the cyclic olefin film is expected to improve an insulating property of the composite filling material and reduce “leakage current”. Since the periphery of glass does not change into an alkaline environment and becomes resistant to hydrolysis, an inlet of a penetration path of water vapor is no longer formed. The present film imparts a delamination-preventing function to the composite filling material.

Furthermore, it was discovered that the thickness of the film has a strong correlation with the prevention of delamination. Cyclic olefin films inherently shrink when environmental temperature equals or exceeds the glass transition temperature. Generally, such cyclic olefin films are commercially available as shrinkable films. Studies revealed that significant shrinking occurs when the environmental temperature exceeds the glass transition temperature by 20° C. or more. While the present composite filling material has an unshrinkable structure and functions as a filling material inside a solar cell module since the composite filling material is compressed and thermally cured at around 150° C. in the lamination process, it was found that hexagonal wrinkles occur when a film thickness of the composite filling material exceeds 50 μm. In the case of a film with a thickness of 50 μm or less, since the respective interfaces are integrated due to cross-linking with EVA molecules, properties of the film interface determine properties of the film itself and shrinking does not occur. Since shrinking that occurs inside a layer induces delamination, the discovery that the film thickness of cyclic olefin film is an extremely important physical property value has led to the present invention. A film thickness of less than 20 μm is unfavorable since a risk of rupture arises in a film winding step.

A resin composition of the (B) layer was determined by adjusting additive amounts and blending temperatures when adding an ultraviolet absorbing agent, an antioxidant, and a light-resistant stabilizer to a masterbatch created prior to formation of the ethylene cyclic olefin film so that the glass transition temperature (Tg) of the masterbatch was lower than the glass transition temperature (Tg) of a raw material resin by 2° C. to 7° C. The glass transition temperature of the masterbatch affects a shrinkage factor of the film. A difference of less than 2° C. means that the additive amount of the stabilizer is too small and is therefore unfavorable. A difference of more than 7° C. may result in a large film shrinkage factor and is therefore unfavorable.

In order to suppress the occurrence of hexagonal wrinkle patterns due to the shrinking of cyclic olefin by a stronger integration with the EVA sealing material, a resin composition in which a silane coupling agent is added to the cyclic olefin resin is more favorable.

In addition, a crystalline solar cell module including the delamination-preventing composite sealing material on both the light-receiving surface and the back sheet-side surface thereof prevents migration of water vapor and metallic ions from the rear surface and is therefore favorable as a module which completely prevents a delamination from occurring over an ultralong period of time.

According to the present invention, a solar cell module with no occurrences of delamination over a long period of time can be provided by simply supplying the delamination-preventing film and the EVA sealing material according to the present invention to a solar cell module processing line or, more specifically, in a standard cure system, a fast cure system, or an ultra-fast cure system without changing the processing conditions. Furthermore, the countermeasure to the cause of delamination occurrence contributes to maximizing power generation over a lifetime of a solar cell module.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic view illustrating a delamination phenomenon;

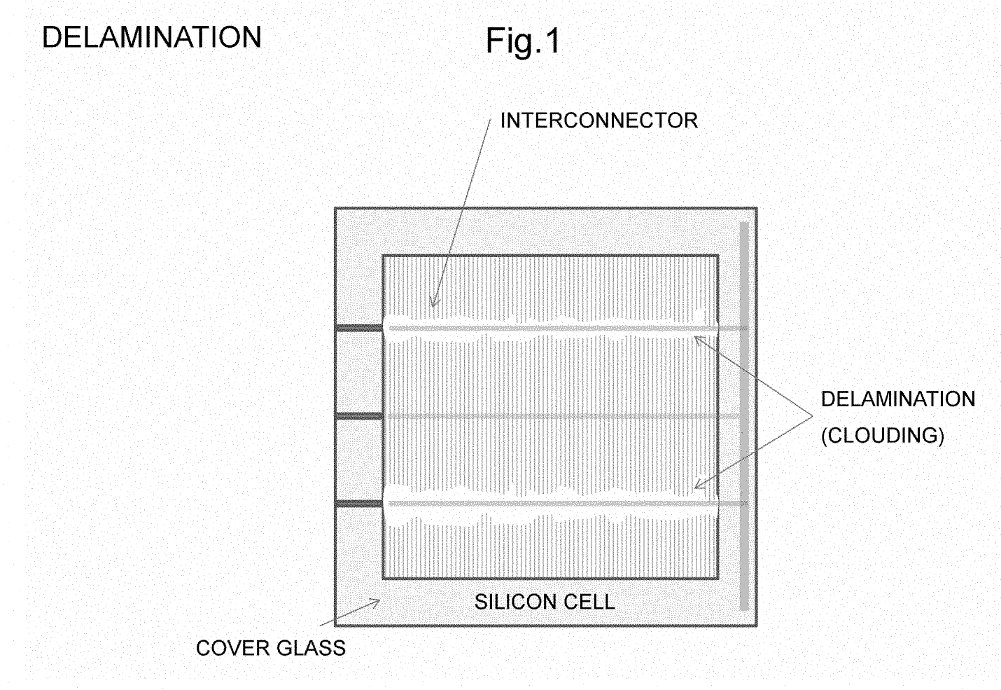

FIG. 2 is a schematic sectional view of a structure of a super straight solar cell module;

FIG. 3 is a schematic sectional view of a composite filling material according to the present invention indicating a layer structure of a composite sealing material in which a cyclic olefin film is sandwiched by EVA sealing materials;

FIG. 4 is a schematic sectional view showing a state of an EVA sealing material covering cells; and

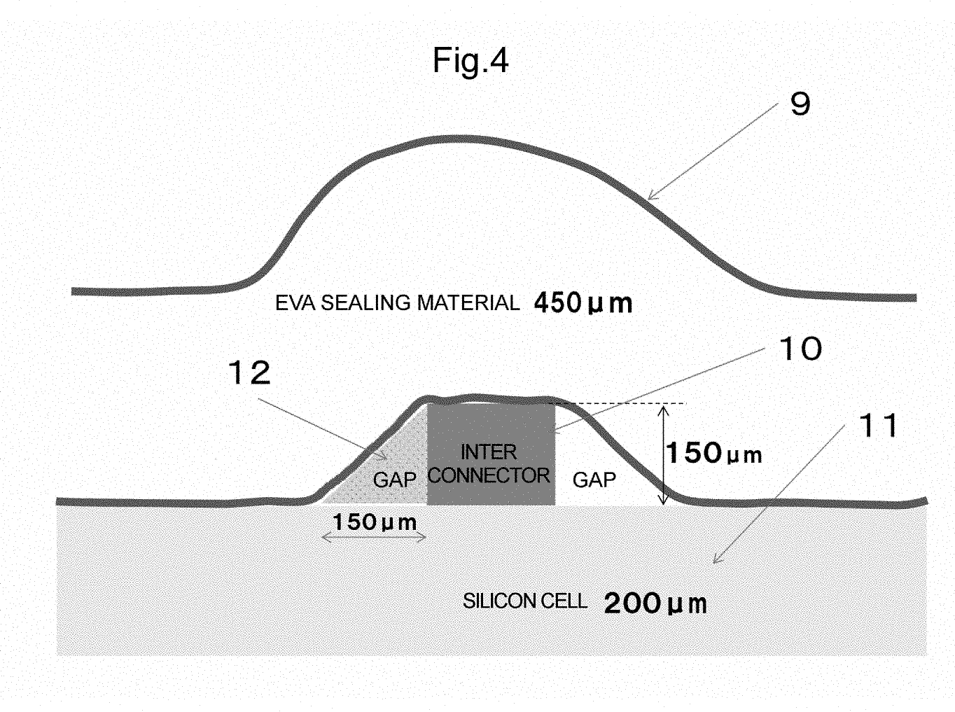

FIG. 5 is a schematic circuit diagram of a delamination test.

### DETAILED DESCRIPTION OF THE PREFERRED EMBODIMENTS

Hereinafter, a delamination-preventing film for a solar cell as an example of an embodiment of the present invention, a method of manufacturing the delamination-preventing film for a solar cell, and a solar cell module using the delamination-preventing film for a solar cell will be described. However, the embodiment described below is not intended to limit the scope of the present invention.

The delamination-preventing film for a solar cell according to the present invention does not independently exhibit a sealing function for a solar cell. Flexibility necessary as a filling material and, most importantly, the capability to retain strong chemical adhesion at an interface between a cover glass and a power generating element over long periods of 40 to 60 years as objects of the present invention are realized as a composite with an EVA sealing material.

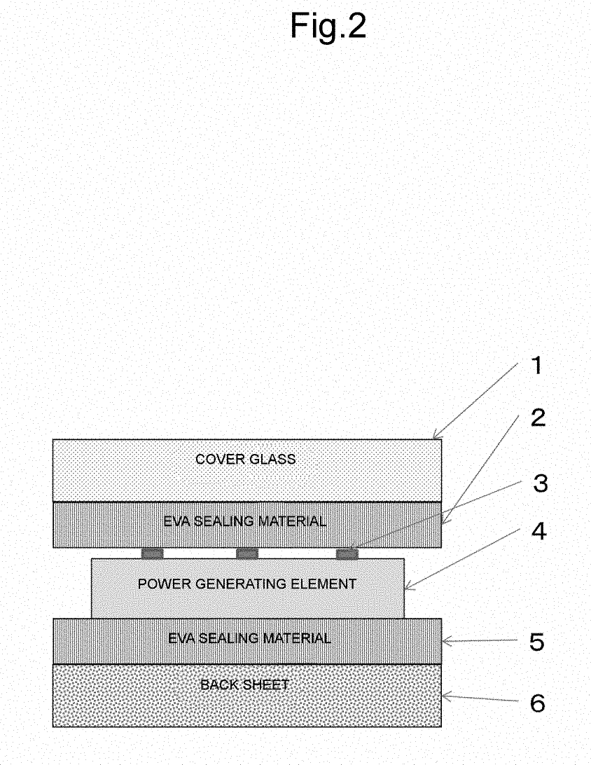

The delamination-preventing film according to the present invention exhibits the effects of the present invention in a mode where the delamination-preventing film is sandwiched by the EVA sealing material between the cover glass and the power generating element or between a back sheet and the power generating element in a super straight structure (FIG. 2).

Delamination-Preventing Film

The delamination-preventing film according to the present invention is constituted by a resin composition having a cyclic olefin-based polymer as a main component. Among cyclic olefin-based polymers, an ethylene-norbornene random copolymer is most favorable. An ethylene-norbornene random copolymer polymerized by a metallocene catalyst or a vanadium catalyst is preferable. In addition, cyclic olefin manufactured using a cyclic olefin component as a starting ingredient, performing ring-opening polymerization with a metathesis catalyst, and subsequently adding hydrogen is also favorable. As the cyclic olefin-based copolymer according to the present invention, TOPAS (registered trademark) (manufactured by TOPAS Advanced Polymers, Germany) or APEL (registered trademark) (manufactured by Mitsui Chemicals, Inc.) can be used.

Resin Composition and Molding Method

An ultraviolet absorbing agent, an antioxidant, and a light-resistant stabilizer are favorably added to the composition of the delamination-preventing film according to the present invention. In addition, the resin composition to which a silane coupling agent is added produces favorable co-crosslinking with the EVA sealing material. A masterbatch of the chemicals are first fabricated and supplied in an operation of an extruder during film formation.

In this case, a kneader was used for compounding. A molding temperature when processing the masterbatch is 180° C. or higher and 300° C. or lower and favorably 230° C. or higher and 290° C. or lower. It was found that this molding temperature heavily exercises an effect on a shrinkage factor of a molded film. It was also found that the shrinkage factor of the film also varies depending on the type and additive amounts of stabilizers and other chemicals that are added for the purpose of retaining the functions according to the present invention.

Intensive studies revealed that a difference between the molding temperature and a glass transition temperature of resin prior to adding the chemicals should range from 2° C. or more and 7° C. or less and favorably 3° C. or more and 6° C. or less and that long-term light resistance with an aim to last 40 years cannot be secured if the difference is less than 2° C. A difference exceeding 7° C. is unfavorable since the shrinkage factor of the cyclic olefin film increases and causes peeling of the interface with the EVA sealing material and, consequently, delamination occurs around the interconnectors.

As the silane coupling agent, a compound selected from the group consisting of a vinyl group, a methacryl group, an acrylic group, and an epoxy group can be used. As the ultraviolet absorbing agent, a benzophenone-based ultraviolet absorbing agent, a benzotriazole-based ultraviolet absorbing agent, a triazine-based ultraviolet absorbing agent, or a salicylate ester-based ultraviolet absorbing agent is favorably added. A hindered amine light stabilizer is favorably added.

Film formation of the solar cell sealing material according to the present invention can be performed by known methods including an extrusion casting method which uses a T-die at a head tip of an extruder and a calendering method. In this case, the film was prepared by an extrusion casting method using a T-die. A temperature of the T-die is 80° C. or higher and 250° C. or lower and favorably 120° C. or higher and 180° C. or lower. A surface of the formed film is favorably subjected to processing such as embossing or roughening for the purpose of preventing blocking.

The film has a thickness of 20 μm to 50 μm and favorably 30 μm to 40 μm. A thickness of less than 20 μm makes a film formation process difficult and is therefore unfavorable. A thickness of more than 50 μm is unfavorable because, when a glass surface reaches a temperature of around 100° C. at a power plant site, film shrinkage of the cyclic olefin-based copolymer occurs and causes “peeling” at the interface with the EVA sealing material and, consequently, delamination occurs. After sandwiching the film according to the present invention by the EVA sealing material and molding the film under prescribed lamination conditions, water vapor permeability was evaluated.

Solar Cell Module

A crystalline solar cell module is created by the following three steps: 1. layup step; 2. lamination step; and 3. framing step. In the layup step, the EVA sealing material, a cell matrix constructed by solder wiring of cell strings in series, and the EVA sealing material are laid on top of a cover glass, and the stack is further covered by a back sheet. The used EVA sealing materials were cut to a size about 5 mm larger than a size of the glass in order to prevent glass edge portions from being exposed due to shifting of the EVA sealing materials or shrinkage caused by processing heat. 2. Lamination step is performed by setting a hot plate temperature, a vacuum time, and a pressurization time (atmospheric pressure). The vacuum time was set to 5 minutes, the pressurization time to 15 minutes, and the hot plate temperature to 150° C.

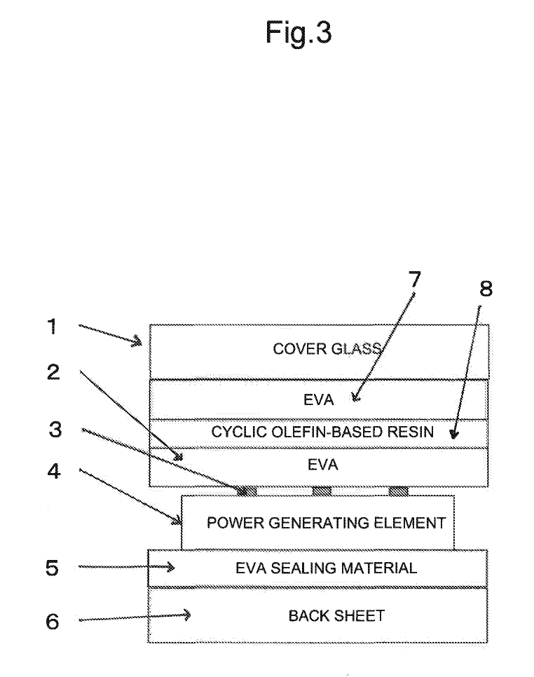

FIG. 3 is a schematic sectional view showing an example of the solar cell module according to the present invention. The solar cell module shown in FIG. 3 includes a transparent glass (a cover glass) 1 of a light-receiving surface, the delamination-preventing composite filling material according to the present invention (including a commercially-available EVA sealing material 7 selected by measuring a melting point, the delamination-preventing film 8 according to the present invention, and a commercially-available EVA sealing material 2 selected by measuring a melting point), an interconnector 3, a solar cell element 4, a commercially-available EVA sealing material 5 selected by measuring a melting point, and a commercially-available back sheet 6.

Solar Cell

Any solar cell capable of generating power by utilizing a photovoltaic effect of a semiconductor can be used and, for example, silicons (monocrystalline, polycrystalline, and amorphous) and compound semiconductors can be used.

Method of Manufacturing Solar Cell Module

Using a commercially-available vacuum laminator, solar cell modules laid up in a 60-series configuration was molded under the following conditions: a vacuum time of 5 minutes, a press time of 15 minutes, and a molding temperature of 150° C. After the molding, a solar cell module was prepared by attaching an aluminum frame and fixing a commercially-available terminal box.

Temperature Distribution on Glass Surface in Lamination Process

In order to provide a simple explanation of the effects of the present invention, using a commercially-available vacuum laminator, the hot plate temperature was set to 150° C., thermocouples were attached to a central portion and edge corner portions on the cover glass of the 60-series configuration, and temperature rises were organized by a variable of processing time. Results were as follows.

TABLE 1

| | Vacuum time (minutes) | | | Press time (minutes) | |
|---|---|---|---|---|---|
| Processing time | 1 | 3 | 5 | 15 | 20 |
| Central portion | 55 | 80 | 125 | 145 | 150 |
| temperature (° C.) | | | | | |
| Edge corner portion | 35 | 60 | 80 | 144 | 150 |
| temperature (° C.) | | | | | |

The results show that during the vacuum time (the preheating step), the temperature rise in the periphery of the glass edge portions is slower than the central portion which is in direct contact with the hot plate. In the press step, after pressurization by a diaphragm rubber sheet, temperatures of the central portion and the periphery portion of the edges of the glass become the same.

### PRACTICAL EXAMPLES

While the present invention will be described in greater detail using practical examples, it is to be understood that the present invention is not limited to the practical examples described below. Various measurements and evaluations with respect to sheets according to the present invention and solar cell modules using the sheets were performed as follows.

(1) Measurement of Glass Transition Temperature and Measurement of Compound ΔTg (° C.)

As glass transition temperatures with respect to the cyclic olefin-based resin, the resin composition, films, and sheets, second-run measured values at a temperature rise rate of 20° C./min taken by a DSC method were adopted. In order to obtain compound ΔTg, after adding prescribed amounts of a stabilizer and the like to the cyclic olefin-based resin using a kneader, a masterbatch compound including the stabilizer and the like was fabricated by kneading, the masterbatch compound was cooled to room temperature, Tg of the masterbatch compound was measured, and a difference between Tg of the masterbatch compound and Tg of a virgin resin was calculated. The compound ΔTg varies depending on the additive amounts of the stabilizer and the like and the temperature and duration of kneading. ΔTg is proportional to the additive amounts. In addition, ΔTg tends to increase when the kneading temperature is higher and a larger workload of kneading is applied. Since ΔTg significantly affects the film shrinkage factor, a range in which the effects of the present invention are manifested is defined by ΔTg.

(2) Evaluation of Shrinkage Factor of Delamination-Preventing Film

Films with various thicknesses and compositions molded using a T-die were cut into 800-mm squares and shrinkage factors (Expression 1) in an MD direction (a direction of resin flow) and a TD direction (a direction perpendicular to the MD direction) were calculated.

Shrinkage factor value=(800 mm−length after heat treatment)/800 mm×10⁴ (1)

In a large gear oven, the films were placed on a 5-mm Teflon (registered trademark) plate and then heated for 30 minutes at 100° C., and lengths after cooling were measured.

(3) Water Vapor Transmission Rate (ASTM F1249)

Water vapor transmission rates were tested using a water vapor transmission tester (PERMATRAN W3/33, manufactured by MOCON, Inc.) under the following conditions: temperature 40° C. and humidity 90% RH. Thickness was set to 900 μm.

(4) Delamination (Clouding) Test

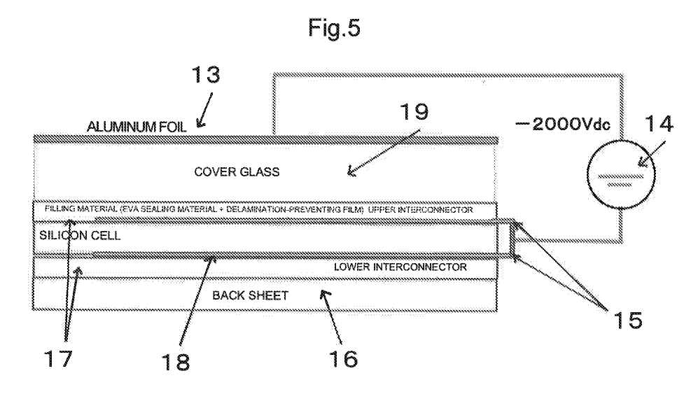

Using TOS7210S manufactured by KIKUSUI ELECTRONICS CORPORATION, −2000 Vdc was applied for 168 hours in a thermostatic chamber under the following conditions: temperature 80° C. and humidity 85% RH. Wiring was performed according to a method recommended by KIKUSUI ELECTRONICS CORPORATION shown in FIG. 5.

Grading was performed as follows. A sensory test method was in accordance with FIG. 5.

Note that “a delamination-free state” according to the present invention corresponds to a score of 4 points or higher.

5 points (highest score): comparison with original reveals absolutely no change in external appearance and can be considered equivalent.

4 points: slight color change (yellowing) is observed around interconnector.

3 points: clouding and peeling of less than 5 mm are observed in at least one interconnector portion of silicon cell.

2 points: clouding and peeling of 5 mm or more and less than 20 mm are observed in at least one interconnector portion of silicon cell.

1 point: clouding and peeling of 20 mm or more are observed in at least one interconnector portion of silicon cell.

(5) Leakage Current Test

Current values measured during the tests described above were recorded.

(6) Light-Resistance Test (Ultraviolet Light-Resistance Test)

Changes in external appearance after 320 hours of continuous irradiation at intensity of metering R: 530 W/m² (300 to 400 nm), BPT 63° C., 50%, and no rain were graded as follows. The effects produced by the present invention correspond to 4 points or higher.

5 points (highest score): comparison with original reveals absolutely no change in external appearance and can be considered equivalent.

4 points: slight color change is observed around interconnector.

3 points: a micro crack of less than 20 mm is present at at least one location around interconnector.

2 points: a micro crack of 20 mm or more is present at least one location in interconnector portion and a hexagonal pattern covering less than 20% of entire cell has occurred on a cell finger electrode portion.

1 point: a micro crack of 20 mm or more is present at least one location in interconnector portion and a hexagonal pattern covering 20% or more of entire cell has occurred on a cell finger electrode portion.

### Practical Examples 1 to 6

### Preparation of Ethylene-Norbornene Random Copolymer Film

As raw materials of the delamination-preventing film, 0.3 parts by mass of 2-hydroxy-4-n-octoxy benzophenone as an ultraviolet absorbing agent and 0.1 parts by mass of bis(2,2,6,6-tetramethyl-4-piperidyl) sebacate as a light-resistant stabilizer were added to 100 parts by weight of TOPAS (registered trademark) 8007. The raw materials were kneaded using a twin screw extruder at 230° C. to obtain a cyclic olefin-based resin composition. Tg of the resin composition and Tg of cyclic olefin TOPAS 8007 were measured to obtain ΔTg. Next, pellets of the resin composition were processed in a 1000 mm-wide T-die portion at a resin temperature of 120° C. to obtain films of various thicknesses. Films with thicknesses of 38 μm, 45 μm, 30 μm, 25 μm, 40 μm, and 35 μm were respectively prepared as practical examples 1, 2, 3, 4, 5, and 6. Film shrinkage values of the obtained films were measured. Water vapor permeability was measured by sandwiching the obtained films by EVA-1 and applying a 900-μm metal spacer to fabricate composite filling materials (thickness: 900 μm) using a press machine.

A solar cell module was created in practical example 1 by stacking the obtained film in a state where the film is sandwiched by a commercially-available EVA with a melting point of 58° C. (the “filling material” according to the present invention) and performing a lamination process under the following conditions: a vacuum time of 5 minutes, a press time of 15 minutes, and a hot plate temperature of 150° C.

Meanwhile, the obtained films were combined with: an EVA sealing material with a melting point of 67° C. in practical example 2; an EVA sealing material with a melting point of 71° C. in practical example 3; an EVA sealing material with a melting point of 67° C. in practical example 4; an EVA sealing material with a melting point of 67° C. in practical example 5; and an EVA sealing material with a melting point of 71° C. in practical example 6.

Comparative examples 1 to 6 differed significantly in film thickness from the practical examples. Film thicknesses of the comparative examples 1, 2, 3, 4, 5 and 6 were, respectively, 150 μm, 200 μm, 150 μm, 150 μm, 75 μm, and 100 μm. Comparative examples 3 and 6 differed from the practical examples in Tg of ethylene-cyclic olefin, with comparative example 3 having Tg of 106° C. and comparative example 6 having Tg of 90° C. Comparative example 7 represented an ordinary solar cell module structure to which only a commercially-available EVA sealing material (with a melting point of 76° C.) was applied.

TABLE 2

| | Practical | Practical | Practical | Practical | Practical | Practical | Comparative |
|---|---|---|---|---|---|---|---|
| | example 1 | example 2 | example 3 | example 4 | example 5 | example 6 | example 1 |
| I-1. | | | | | | | |
| Delamination-preventing | | | | | | | |
| film | | | | | | | |
| 1. | | | | | | | |
| Ethylene-norbornene | | | | | | | |
| random copolymer blend | | | | | | | |
| composition | | | | | | | |
| TOPAS 8007 | 100 | 50 | 20 | 100 | 50 | | 50 |
| TOPAS 9506 | | 50 | 80 | | 50 | | 50 |
| TOPAS 5013 | | | | | | | |
| APL 6509T | | | | | | 100 | |
| 2. Glass transition | 77 | 73 | 70 | 77 | 72 | 79 | 73 |
| temperature: Tg (° C.) | | | | | | | |
| 3. Film thickness (μm) | 38 | 45 | 30 | 25 | 40 | 35 | 150 |
| 4. Compound ΔTg (° C.) | 4 | 3 | 5 | 2 | 5 | 4 | 1 |
| 5. Film shrinkage | | | | | | | |
| value | | | | | | | |
| MD direction | 2 | 3 | 2 | 3 | 3 | 14 | 320 |
| TD direction | 2 | 2 | 2 | 2 | 2 | 10 | 250 |
| 6. Water vapor | 0.25 | 0.20 | 0.35 | 0.60 | 0.30 | 0.28 | 0.65 |
| permeability | | | | | | | |
| (g · mm/m² · d) | | | | | | | |
| I-2. Combination/ | | | | | | | |
| commercially-available | | | | | | | |
| EVA sealing | | | | | | | |
| material | | | | | | | |
| EVA-1 (Tm: 58° C.) | ∘ | | | | | | |
| EVA-2 (Tm: 67° C.) | | ∘ | | ∘ | ∘ | | ∘ |
| EVA-3 (Tm: 71° C.) | | | ∘ | | | ∘ | |
| EVA-4 (Tm: 75° C.) | | | | | | | |
| II Solar cell module | | | | | | | |
| product test | | | | | | | |
| 1. Leakage current (A) | 3E−5 | 2E−5 | 4E−5 | 6E−5 | 2E−5 | 3E−5 | 2E−4 |
| 2. Delamination test | 5 | 5 | 5 | 5 | 5 | 5 | 2 |
| 3. Light-resistance | 5 | 4 | 5 | 4 | 5 | 5 | 2 |
| test | | | | | | | |

| | Comparative | Comparative | Comparative | Comparative | Comparative | Comparative |
|---|---|---|---|---|---|---|
| | example 2 | example 3 | example 4 | example 5 | example 6 | example 7 |
| I-1. | | | | | | |
| Delamination-preventing | | | | | | |
| film | | | | | | |
| 1. | | | | | | |
| Ethylene-norbornene | | | | | | |
| random copolymer blend | | | | | | |
| composition | | | | | | |
| TOPAS 8007 | 20 | 100 | 90 | 90 | 80 | |
| TOPAS 9506 | 80 | | | | | |
| TOPAS 5013 | | | 10 | 10 | 20 | |
| APL 6509T | | | | | | |
| 2. Glass transition | 79 | 106 | 84 | 84 | 90 | |
| temperature: Tg (° C.) | | | | | | |
| 3. Film thickness (μm) | 200 | 150 | 150 | 75 | 100 | |
| 4. Compound ΔTg (° C.) | 1 | 3 | 2 | 1 | 3 | |
| 5. Film shrinkage | | | | | | |
| value | | | | | | |
| MD direction | 450 | 180 | 160 | 90 | 190 | |
| TD direction | 300 | 160 | 140 | 70 | 150 | |
| 6. Water vapor | 0.90 | 0.78 | 0.70 | 0.65 | 0.45 | 2.50 |
| permeability | | | | | | |
| (g · mm/m² · d) | | | | | | |
| I-2. Combination/ | | | | | | |
| commercially-available | | | | | | |
| EVA sealing | | | | | | |
| material | | | | | | |
| EVA-1 (Tm: 58° C.) | | | | | | |
| EVA-2 (Tm: 67° C.) | | | ∘ | ∘ | ∘ | |
| EVA-3 (Tm: 71° C.) | ∘ | | | | | |
| EVA-4 (Tm: 75° C.) | | ∘ | | | | ∘ |
| II Solar cell module | | | | | | |
| product test | | | | | | |
| 1. Leakage current (A) | 1E−4 | 3E−4 | 2E−4 | 6E−4 | 3E−4 | 1E−2 |
| 2. Delamination test | 2 | 2 | 2 | 2 | 2 | 1 |
| 3. Light-resistance | 2 | 3 | 3 | 3 | 2 | 5 |
| test | | | | | | |

As a thermal property of the filling material constituted by a composition of the delamination-preventing film and the EVA sealing material, since an EVA sealing material with a melting point of 75° C. or lower is applied as compared to a temperature of a periphery of a module edge portion which is reached within the vacuum time under lamination conditions, the gap created between the EVA sealing material and the interconnector is filled and the designed adhesive strength is obtained. In addition, since Tg of the cyclic olefin film is 80° C. or lower, the cyclic olefin film does not impede the filling of the gap in any way as an intermediate layer of the composite filling material. Meanwhile, it was discovered that, in the case of films with a film thickness of 50 μm, shrinkage hardly occurred after the films were incorporated into a solar cell module even when the temperature of the solar cell module was high (for example, 100° C.). This discovery culminated in the present invention.

Furthermore, laminating the cyclic olefin film inside a solar cell module significantly reduces the “leakage current” which flows through a frame portion in the peripheral portion of the module, suppresses migration of sodium extracted from glass, reduces the likelihood of an occurrence of hydrolysis of the EVA sealing material directly in contact with the cell, and realizes the prevention of delamination. Irradiating the cyclic olefin film with ultraviolet light increases the risk of occurrences of hexagonal wrinkle patterns. When compound ΔTg within the scope of the present invention ranges from 2° C. to 7° C., no delamination occurs as a composite filling material. Comparative example 7 represents an ordinary solar cell module. When a sheet containing an EVA sealing material with a high melting point was adopted in a solar cell module, an adhesive reaction around interconnectors was insufficient and the worst results in the delamination tests were produced.

The present invention provides a filling material obtained by compositing a delamination-preventing film and an EVA sealing material capable of producing a solar cell module in which delamination does not occur even in the most severe environments, and a solar cell module using the filling material is capable of providing a product that is absolutely delamination-free.

1. A delamination-preventing composite sealing material constituted by a three-layer structure of (A) an ethylene-vinyl acetate copolymer (EVA) sealing material/(B) an ethylene-cyclic olefin copolymer film/(A)the EVA sealing material, the delamination-preventing composite sealing material satisfying qualities of (A) and (B) below as a filling material for a super straight-type solar cell module:
(A) a melting point (Tm) of the EVA sealing material as measured by DSC ranges from 55° C. to 75° C.; and
(B) a glass transition temperature (Tg) of the ethylene-cyclic olefin as measured by DSC ranges from 70° C. to 80° C. and a film thickness thereof ranges from 20 μm to 50 μm.

2. The delamination-preventing composite sealing material according to claim 1, wherein
a resin composition of the (B) layer is obtained by adding an ultraviolet absorbing agent, an antioxidant, and a light-resistant stabilizer to a masterbatch created prior to formation of the ethylene cyclic olefin film so that a glass transition temperature (Tg) of the masterbatch is lower than a glass transition temperature (Tg) of a raw material resin by 2° C. to 7° C.

3. The delamination-preventing composite sealing material according to claim 2, wherein
a silane coupling agent is added to the resin composition.

4. A crystalline solar cell module, comprising the delamination-preventing composite sealing material according to claim 1 on both a light-receiving-side surface and a back sheet-side surface thereof.
